(19) United States
(12) Patent Application Publication
(10) Pub. No.: US 2012/0217928 A1
(43) Pub. Date: Aug. 30, 2012

(54) ELECTRIC VEHICLE CHARGING INTERFACE

(75) Inventors: Ara Kulidjian, La Jolla, CA (US); Aaron E. Martlage, San Diego, CA (US)

(73) Assignee: Juice Technologies LLC, Columbus, OH (US)

(21) Appl. No.: 13/219,734

(22) Filed: Aug. 29, 2011

Related U.S. Application Data
(60) Provisional application No. 61/447,517, filed on Feb. 28, 2011.

(51) Int. Cl. H01H 83/00; H02J 7/00; G01R 19/00; H02H 11/00

(52) U.S. Cl. 320/109; 307/125; 307/131; 307/326; 324/76.11

(57) ABSTRACT

An electric vehicle charging connection (EVCC) includes metering logic within a socket that supplies electricity to a plug-in cord, and metering logic within a handle of the plug-in cord. The handle and socket compare metering information from the metering logic, and electrical flow from the socket is disabled based on results of the comparison.

### PRIORITY CLAIM

This application claims benefit of U.S. Provisional Patent Application No. 61/447,517 filed 28 Feb. 2011 which is incorporated by reference herein in its entirety.

### BACKGROUND

Electric vehicles (both hybrid and all electric) need to interface with the electricity grid in order to renew their stored supply of energy. Energy suppliers (such as utility companies, independent power producers, generation entities, trading and marketing entities, aggregators, transmission or distribution providers) need to properly manage electricity supply and demand and properly bill for electricity used by these vehicles regardless of where the vehicles are charged.

There therefore exists a need for a secure means of connecting vehicles to the electrical grid in a manner which allows vehicle owners to control and to be accountable for their use of electricity, and allows third party energy providers to manage and measure electricity loads, storage, and generation associated with electric vehicles. There is additionally a need for a means of readily providing a consumer with information regarding the charging status of the vehicle.

### BRIEF DESCRIPTION OF THE DRAWINGS

FIG. 1 is a schematic of one embodiment of a EVCC handle, where operation of the handle is controlled by a microcontroller with embedded flash memory.

FIG. 2 is a schematic of one embodiment of a smart socket where operation of the smart socket is controlled by a microcontroller with embedded flash memory.

FIG. 3 is a flowchart of one embodiment of a process for operating the microcontroller in the handle of FIG. 1.

FIG. 4 is a flowchart of one embodiment of a process for operating the microcontroller in the smart socket of FIG. 2.

FIG. 5 is a timing diagram for connection of the handle of FIG. 1 between a plug-in vehicle and the smart socket of FIG. 2, which forms a public or semi-public outlet.

FIG. 6 is a timing diagram for connection of the handle of FIG. 1 between a plug-in vehicle and a conventional socket, which forms a private outlet.

FIG. 7A is a side view of an embodiment of the smart socket with prongs for preventing unauthorized disconnection from the handle.

FIG. 7B is a front view of an embodiment of the smart socket with prongs for preventing unauthorized disconnection from the handle.

FIG. 7C is a top view of an embodiment of the smart socket with prongs for preventing unauthorized disconnection from the handle and showing how the smart socket connects to the handle.

FIG. 8A is a top view of an embodiment of the handle with a tether cable and securing bracket for preventing unauthorized disconnect of the vehicle plug from the handle.

FIG. 8B shows an embodiment of the securing bracket with non-standard screw heads.

FIG. 9 is a view of an embodiment of an electric vehicle charging connection (EVCC) charging a vehicle.

FIG. 10 is an exemplary depiction of an EVCC handle.

FIG. 11A is a depiction of an embodiment of an EVCC handle; FIG. 11B is a depiction of an embodiment of an inset display in an EVCC handle.

FIG. 12 is a view of an embodiment of dual metering logic in an EVCC.

FIG. 13 illustrates an embodiment of an EVCC including GFCI logic and an expansion module.

### DETAILED DESCRIPTION

Preliminaries

References to “one embodiment” or “an embodiment” do not necessarily refer to the same embodiment, although they may. Unless the context clearly requires otherwise, throughout the description and the claims, the words “comprise,” “comprising,” and the like are to be construed in an inclusive sense as opposed to an exclusive or exhaustive sense; that is to say, in the sense of “including, but not limited to.” Words using the singular or plural number also include the plural or singular number respectively, unless expressly limited to a single one or multiple ones. Additionally, the words “herein,” “above,” “below” and words of similar import, when used in this application, refer to this application as a whole and not to any particular portions of this application. When the claims use the word “or” in reference to a list of two or more items, that word covers all of the following interpretations of the word: any of the items in the list, all of the items in the list and any combination of the items in the list, unless expressly limited to one or the other.

“Logic” refers to machine memory circuits, machine readable media, and/or circuitry which by way of its material and/or material-energy configuration comprises control and/or procedural signals, and/or settings and values (such as resistance, impedance, capacitance, inductance, current/voltage ratings, etc.), that may be applied to influence the operation of a device. Magnetic media, electronic circuits, electrical and optical memory (both volatile and nonvolatile), and firmware are examples of logic.

Those skilled in the art will appreciate that logic may be distributed throughout one or more devices, and/or may be comprised of combinations memory, media, processing circuits and controllers, other circuits, and so on. Therefore, in the interest of clarity and correctness logic may not always be distinctly illustrated in drawings of devices and systems, although it is inherently present therein.

The techniques and procedures described herein may be implemented via logic distributed in one or more computing devices. The particular distribution and choice of logic is a design decision that will vary according to implementation.

Herein the term “electric vehicle charging connection” or EVCC refers to all logic between and including a smart socket and/or expansion module (see descriptions of these elements below) and a handle that interfaces to an electric vehicle charging port.

The term “intermediate logic” between two elements in the EVCC refers to logic that consumes power after one of the elements and before a second of the elements.

The term “pistol shape” refers to a shape comprising a hand grip portion and a barrel portion that turns approximately (though not necessary exactly) ninety degrees from the hand grip.

The term “consisting of exactly” certain elements means that something includes exactly those elements and no other elements of the same general type. For example, “consisting of exactly” certain wires means a cord has those wires and no other wires, but the cord may include other elements that aren't wires, such as insulation or an EMI shield.

Overview

A modularized electric vehicle charging connection (EVCC) between a power outlet and an electric vehicle is described that allows vehicle owners to control and be accountable for their vehicle's use of electricity. The modular EVCC also facilitates management and measurement of energy usage and loading by third party energy suppliers including, but not limited to, utility companies, independent power producers, electrical generation entities, transmission or distribution providers, and trading and marketing entities. The EVCC can display, receive, and transmit data regarding the charging status and conditions under which the vehicle may be charged from both the consumer and/or the energy supplier.

The EVSE may comply with industry standards such as the Society of Automotive Engineers J1772™ Electric Vehicle Conductive Charge Coupler, IEC 62196, or JAM Level 3 DC. In general, these standards cover the physical, electrical communication protocol, and performance requirements for an electric vehicle charging system and coupler.

The EVSE may work with a standard electrical outlet (e.g. 110V, 115V, 120V, 220V, 127V, 230V, 110/220V, 120-127V, 127/230V, 100V, 127/220V, 220/230V, 231V, 240V), or a dedicated electrical outlet (110V, 240V or 480V) or a smart socket which may be permanently or removably attached to an electrical outlet. An expansion socket may be provided to enhance, in a modular way, the functionality of the EVCC. The expansion module may couple between the smart socket and the electrical outlet.

The EVCC comprises a communications interface for allowing communication, cellular, wired or wireless, between the module and the energy provider, the module and the consumer and/or the consumer and the energy provider. The communications interface may include a communications chip configured to allow communications with an access point (i.e., meter) of the energy provider's (such as a local electric utility) Advanced Metering Infrastructure (AMI), Home Area Network (HAN) or Internet. The access point may be a wireless chip attached to a meter that can wirelessly communicate with the module, or the communications interface may be separate from the home area network and may be dedicated to communication with the energy provider such as a local utility, or it may share a communications interface for communication with the energy provider such as a local utility.

The EVCC may include logic to enable consumers to determine: (1) at what time and/or for how long the vehicle charges, (2) at what rate the vehicle charges, (3) at what rate the vehicle discharges energy, (4) at what energy price the vehicle charges, (5) when the vehicle returns energy to the grid, (6) at what price the vehicle returns energy to the grid, (7) if the vehicle is charging, idle or returning energy to the grid, (8) if the module, socket and/or vehicle are communicating, (9) the status of the connection, and (10) the status of the electrical grid from the energy supplier or other energy contracting agency. Such information may be displayed on the EVCC or accessed on a smart phone, computer, tablet, cloud application or other independent device that displays, transmits, and receives data from and between the vehicle, consumer and energy provider.

The EVCC may include security logic for authenticating the owner (energy user) and/or the billing entity at each use, such as through a key, keyless entry device, a password or other security code, or biometric identification including, but not limited to, fingerprints, retinal scans, facial recognition, palm prints, hand geometry and iris recognition. In some embodiments, a user may assign the expense of charging the vehicle to one or more accounts, or with one or more identifiers. For example, if the vehicle owner travels to visit different clients, recharging the vehicle may be billed to the client visited or the account of that client. When authentication is successful, the EVCC is enabled, but otherwise remains disabled.

The EVCC is capable of at least two modes of operation, with a first mode comprising use with a smart socket that forms a public or semi-public connection to the energy grid, and a second mode comprising use with a conventional electrical outlet. In the first mode of operation, once enabled, the EVCC will communicate a unique access code to the energy provider or Internet-based system via the communication interface of the smart socket. The energy provider will validate the code, which may be tied to the EVCC owner's utility account or other billing mechanism. Once validated, the energy provider will signal the smart socket to enable energy to flow to or from the EVCC.

The EVCC may periodically or upon authentication or request receive pricing information from the appropriate sources. This pricing information may be used by the EVCC to determine the cost, credits, or discounts to the user for charging or discharging. The pricing information may be applied by the EVCC to determine when to charge or discharge, the rate to charge or discharge, and the duration to charge or discharge. The cost, credits, or discount from a charging or discharging event may be calculated based on charging or discharging time and total energy charged or discharged, may include access fees, demand charges, or may be a flat fee for the rights to charge or discharge the vehicle. In some embodiments, the EVCC may preserve a record of the costs or credits for the charging or discharging activities of the vehicle.

User preferences may be programmed into or EVCC through the communication interface, via a separate USB port, cellular, IEEE 802.11 (Wi-Fi), IEEE802.15.4 (ZigBee) radios, Bluetooth, Wi-Max, satellite, PLC communication, RFID or any other such devices.

The EVCC may be pre-programmed with the user's energy provider account information or other billing information. When the EVCC is authenticated, the code sent to the energy provider may identify the account or other billing information. The EVCC may also be pre-programmed with user preferences regarding desired energy pricing or charging times. For example, user preferences may indicate the user does not wish to pay more than a predetermined rate, e.g., 10 cents per kilowatt hour, or that the user only wishes charging to occur between certain off-peak hours, for example, between 11 PM and 7 AM, to take advantage of off-peak pricing.

The user may program or select variable options when they activate the EVCC. For example, they may normally wish charging to occur between certain off-peak hours, but if they are using the vehicle more than usual in one particular week, they may want the vehicle to charge every time they activate the EVCC that week. The user may program or select variable options remotely so that if situations change, they can change the charging parameters and conditions. The user may program charging options and include an override condition, so that the vehicle will be fully charged by a particular time regardless of the specific circumstances. For example, the user may specify a preference for charging at a particular price point or a particular time of day, but require that the vehicle be fully charged by 7:30 am regardless of these conditions, or that the vehicle always be maintained at a particular charge level regardless of these conditions.

Other user preferences may allow discounts or credits for electricity use if the user authorizes the utility to discharge the vehicle during times of peak electricity usage, thus providing a source of electricity to the grid. Users may receive charging discounts or credits by charging and/or discharging into the grid to meet grid management needs (e.g. congestion, renewable integration, power quality maintenance, load and resource balancing). Some or all of these features may be overridden by the user and/or energy provider depending on the situation. For example, a user may choose to charge a vehicle regardless of the energy price or time of day or an energy provider may charge, stop charging or drain the vehicle during emergency situations. In some embodiments, the module may be re-programmed but only by the energy provider and then only after verification of the identity of the owner is performed. In other embodiments, the user may override pre-programmed settings. In further embodiments, the user may reprogram the preferences at any time or select from a menu of options.

The EVCC will only allow energy to flow to the vehicle if user preferences, if any, are satisfied. Thus, if the user indicates a preference to pay no more than 10 cents per kilowatt hour, or for energy charging to occur only during off-peak hours, the EVCC will not allow the energy to flow until these conditions are satisfied. The flow of energy is controlled by a pulse width modulation (PWM) pilot signal sent from the EVCC to the vehicle, and using communication between the handle and the socket. In some embodiments, PWM signal generator logic is physically separated from the personal safety system (e.g., GFCI) logic in the EVCC.

Once the EVCC is enabled, the user's access code and/or account information is transmitted via the communication interface to the energy provider. Electricity which passes through the EVCC, either to or from the vehicle, is metered by the module. A dual metering mechanism is employed to help prevent the theft of energy. This mechanism is described in more detail at a later point in this document. When the EVCC is disconnected, the metered data is transmitted via the communications interface to the energy provider or Internet-based service so that it can be billed to the appropriate account. The account for the utility meter through which the energy was drawn may be then credited with an offsetting amount.

Once the flow of energy is discontinued (e.g. the EVCC is unplugged from the smart socket), the handle may be automatically disabled. This automatic disabling helps prevent theft of electricity and deter theft of the handle because it will not be usable by anyone other than the owner. An optional anti-theft feature is to enable EVCC to physically lock onto the vehicle so it can only be removed with a key or user validation (password or other secure technique, such as biometric scan). In some embodiments, the handle is not disabled when disconnected from the vehicle, even though electricity no longer flow to the vehicle. The handle may still for example communicate with the power supplier for updates on electricity rates.

In the second mode of operation, the EVCC communicates with the energy provider through the vehicle owner's HAN or other communications device, and identifies the charging device as a plug-in vehicle. The EVCC will confirm the identity of the vehicle as a plug-in vehicle as obtained from the vehicle's built-in VIN chip or through the high amperage required for vehicle charging.

The EVCC may be actively or pre-programmed with user preferences regarding energy pricing or charging time periods, and the energy flow will only commence once these conditions, if any, are satisfied. The EVCC may display status information such as on/off, testing, charging, charge complete, not charging, idle, draining, energy pricing, demand or access fees, locking status, grid status indicators, errors or any other information that would be useful to the user.

The EVCC may include an override button to override preprogrammed conditions. For example, if the EVCC has stopped charging the vehicle due to a high price of electricity or a utility demand reduction event, the user has the ability to turn charging of the vehicle back on again by pressing the override button.

The EVCC may send status information to a device such as a smart phone, tablet, computer, PDA, cloud application or other such device. The EVCC or module may transmit status data to a smart phone, computer, tablet, cloud application or other independent device.

To prevent device theft and unauthorized disconnection during charging, secure connections may be provided between the handle and the vehicle, and/or between the handle and the smart socket or standard outlet. The secure connection(s) may be released upon authentication of the energy user at each use such as through a key, keyless entry device, a password or other security code, or biometric identification including, but not limited to, fingerprints, retinal scans, facial recognition, palm prints, hand geometry and iris recognition. When authentication is successful, energy flow is enabled, but otherwise remains disabled.

Exemplary Configurations

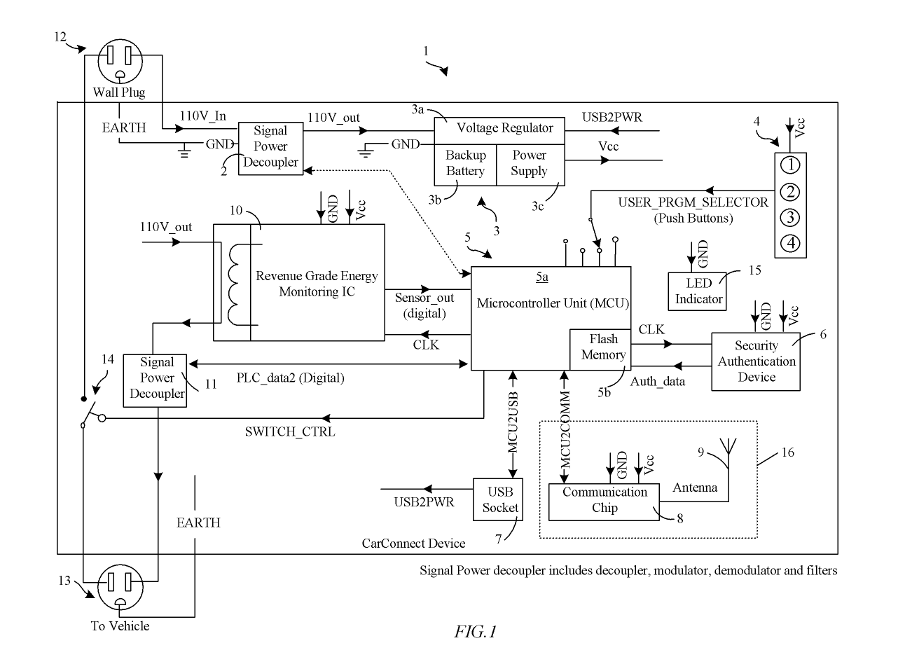

FIG. 1 illustrates an embodiment of a handle 1 that is part of an EVCC between the vehicle's charging interface and an outlet that connects to the energy grid. In one implementation, as shown, a male plug from the vehicle's charging interface plugs into a corresponding female socket 13 on the handle 1, and a male plug 12 on the module plugs into a corresponding female socket connected to the energy grid.

Microcontroller unit (MCU) 5, comprising processor core 5a, embedded flash memory 5b, analog to digital converter (ADC) (not shown), and several programmable input/output peripherals (not shown), controls handle operation. In one embodiment, it also synchronizes the data retrieved from the energy sensor 10 (to be described later) prior to transmitting it to the energy provider such as a local utility via the communications interface or PLC. A flowchart depicting the operation of MCU 5 will be presented later.

The flash memory 5b is non-volatile memory that stores certain pre-programmed information, such as the user's utility account information and access code, and also user preferences regarding energy pricing and desired charging times. This information may be pre-programmed into the flash memory 5b through a number of suitable means, including the Internet, a USB port (e.g., USB socket 7), the communications interface 16, which is described later, a Wi-Fi connection or PLC.

Communications interface 16, comprising communication chip 8 and antenna 8, is configured, in one embodiment, to wirelessly communicate data from the MCU 5 to the energy provider via the access point (i.e., meter) in the outlet owner's home or via the HAN using a suitable protocol, including but not limited to Wi-Fi (802.11), ZigBee (802.15.4), Wi-MAX (8-2. 16), Bluetooth, satellite, PLC, and RFID. In another embodiment, the communications interface 16 is configured to communicate data from the MCU 5 to the energy provider via a wired link. The connection formed by communications interface may either be downlink only (i.e., from the module to the utility) or bi-directional. LED indicator 15 is configured to provide a visual indication when the handle 1 is waiting for the end user to authenticate himself/herself, if required by the embodiment.

Security authentication device 6 is any suitable device for authenticating the identity of the end user. Options include biometric scanners, password keypad, card swiper, keyless entry, keys, etc.

User program selector 4 allows a user to set or change charging preferences (charge immediately, charge at certain time of day, respond to price signals, etc).

Energy sensor 10 is an IC that senses bi-directional energy flow through the handle 1 and outputs a digital signal indicative of a characteristic of the energy flow, e.g., amperage. This information is periodically transmitted to the MCU 5, which may in turn communicate the information to the energy provider via communications interface 16.

Signal power decoupler 2 separates the mixed power signal from plug 12, which may either be inserted into a smart socket or a conventional socket, into a 110 V (60 Hz) AC power signal and data, if any, that was previously modulated onto the power signal and communicated via PLC (Power Line Carrier). As will be discussed, in the case where the plug 12 is connected to a smart socket, data communicated to the handle 1 via PLC comprises an identifier of the socket and its associated meter. Signal power decoupler 11 combines the 110V, 60 Hz power signal with data, if any, to form a mixed signal that is communicated to the vehicle via the vehicle charging interface socket 13.

The voltage regulator 3 regulates the DC voltage of power supply 3c to maintain it at constant voltage level, Vcc. The backup battery 3b powers the handle 1 before energy flow from the energy grid is enabled.

Switch 14 is normally closed, and opens if the handle is disconnected from the vehicle.

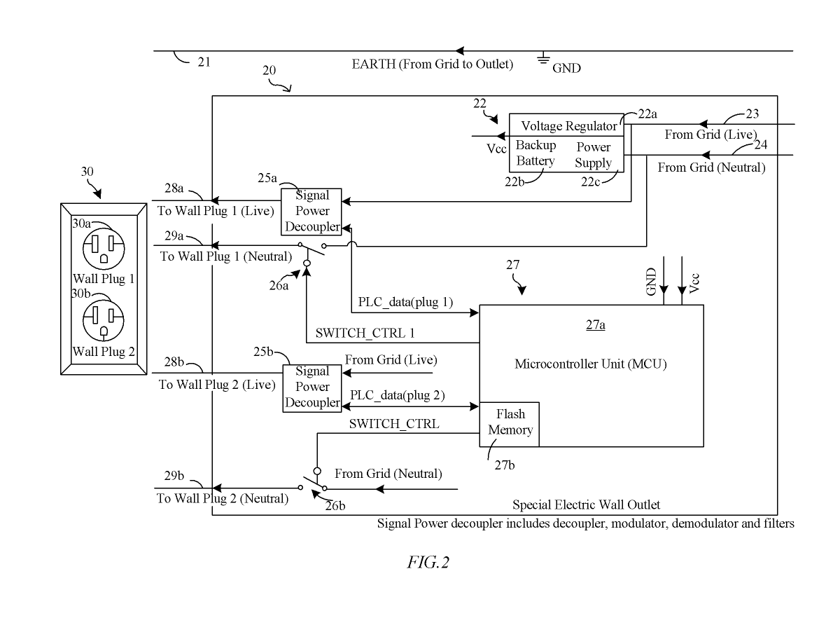

FIG. 2 is a schematic of smart socket 20, which embodies or functions as a public or semi-public outlet. It forms part of the EVCC and is used to couple the handle 1 to the energy grid.

As shown, in one implementation, socket 20 comprises one or more female outlets 30a, 30b, each corresponding to male plug 12 from the handle 1 of FIG. 1. Each of the outlets 30a, 30b is coupled to the energy grid through earth (line 21), grid live (line 23) and grid neutral (line 24) lines.

Microcontroller unit (MCU) 27 comprises processor core 27a, embedded flash memory 27b, analog to digital converter (ADC) (not shown), and several programmable input/output peripherals (not shown). More specifically, MCU 27 is responsible for controlling the functionality of the socket 20 when a handle 1 is connected to it, including communicating meter and socket identification information to the handle 1 via PLC. It also controls a relay (switches 26a, 26b), which, when closed, allows electricity to flow to the handle. The switches 26a, 26b are closed initially and allow power to flow. If authentication of the user fails, or if dual metering detects inconsistencies in the power flow, the switches are opened.

The voltage regulator 22 regulates the DC voltage of power supply 22c to maintain it at constant voltage level, Vcc. In one embodiment, backup battery 22b powers the socket 20 before energy flow from the energy grid is enabled. In another embodiment, the backup battery 22b is located in the handle 1. Thus, an EVCC may comprise a handle 1 that is powered until an authentication of a user fails, the handle comprising a backup battery, and the socket 20 not including a backup battery.

Signal power decoupler 25a combines the 110V, 60 Hz grid live power signal from line 23 with data, if any, from MCU 27 to form a mixed signal that is communicated to the handle 1 over line 28a. Signal power decoupler 25b combines the 110V, 60 Hz grid neutral power signal from line 24 with data, if any, from MCU 27 to form a mixed signal that is communicated to the handle 1 via line 29a.

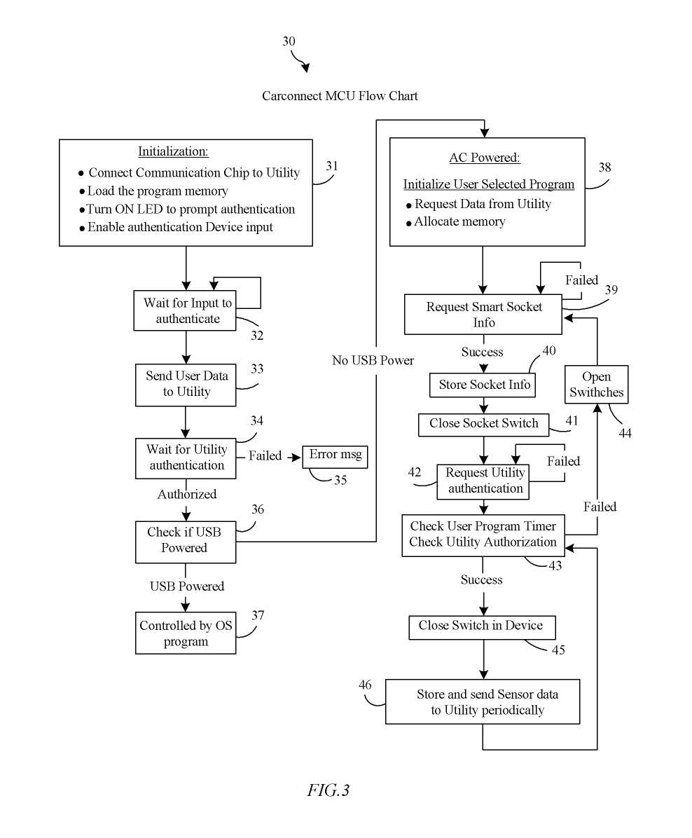

FIG. 3 is an embodiment of a flow chart 30 depicting the operation of MCU 5 in FIG. 1. As will be appreciated, this flow chart represents acts carried out by MCU 5 in response to the operation and application of logic, such as embodied by flash memory 5b, but also potentially by volatile memory, such as RAM.

This flowchart depicts the first mode of operation, when the connection to the energy grid occurs by connecting the module to a public or semi-public outlet.

In block 31, the MCU 5 guides the handle 1 through initialization, which includes establishing a connection to the energy provider through the communications interface 16, loading the program memory (i.e., RAM), with the MCU software, turning on the LED 15 to prompt the end user to authenticate himself/herself, and enabling the security authentication device 6 to receive input or implicitly authenticating the user without user input using an embedded unique ID in the cord. In one embodiment, as discussed, the connection is a wireless connection that is established with an access point (i.e., the meter for the outlet) in the outlet owner's HAN.

From block 31, the process proceeds to block 32. In block 32, the process loops, waiting for the end user to authenticate himself/herself via security authentication device 6 using a password, fingerprint, or other secure technique such as a biometric scan. Upon the user doing so, the process proceeds to block 33.

In block 33, the handle 1, via the communications interface 16, transmits user data (e.g., a unique access code associated with the user's account), that was pre-programmed and stored in the flash memory 5b, to the energy provider via the communications interface (e.g., the HAN for the owner of the public or semi-public outlet). The process then proceeds to block 34 where the process waits for the utility to authenticate the user code. If the utility fails to authenticate the code, or affirmatively indicates that the code failed, i.e., by communicating a “failed” message via PLC to the module, the process outputs an error message, represented by block 35.

However, if the utility authenticates the code, it communicates an “authorized” message to the module via PLC, and then jumps to block 36.

In block 36, the process checks to see if the handle 1 is being powered through the USB port 7, indicating that a host processor is coupled to the handle 1. If so, as indicated in block 37, the host operating system is given control of the handle 1.

If, on the other hand, the handle 1 is intended to be AC-powered, the process jumps to block 38. In block 38, pre-programmed information, if any, reflecting user preferences is retrieved and stored in memory, and data needed to implement those preferences, i.e., pricing, is requested from the utility, either via the communications interface 16 (if the connection is bi-directional) or BPL (if the connection via communications interface 16 is downlink-only). From block 38, the process proceeds to block 39.

In block 39, the handle 1 requests, via PLC, that the smart socket 20 inform it of its identity and that of its related meter. If the request yields the desired information, the process then jumps to block 40.

In block 40, the process stores this information within the handle 1 (e.g., within the flash memory 5b). The process then jumps to block 41.

In block 41, the handle 1 requests, via PLC, that MCU 27 close switches 26a and 26b, enabling the smart socket 20. (At this point, switch 14 within the handle 1 is still open, thus preventing energy flow). The process then jumps to block 42.

In block 42, the handle 1 again requests utility authorization, and loops until the necessary authorization is received. Once the authorization is received, the process proceeds to block 43.

In block 43, the process checks whether the conditions implied by the pre-programmed user preferences, if any, have been satisfied. If so, the process jumps to block 45.

In block 45, MCU 5 is directed to close the switch 14 within the handle 1, thus enabling power to flow. The process then proceeds to block 46.

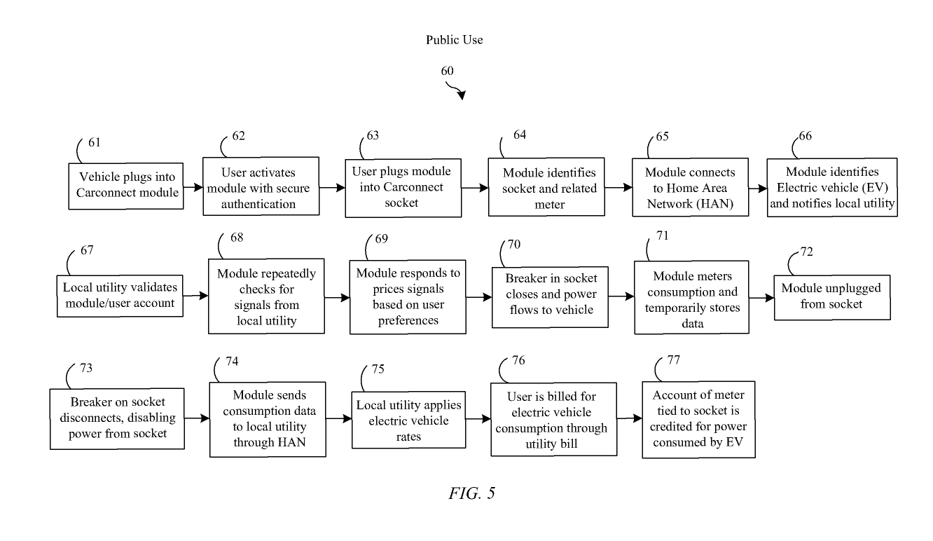

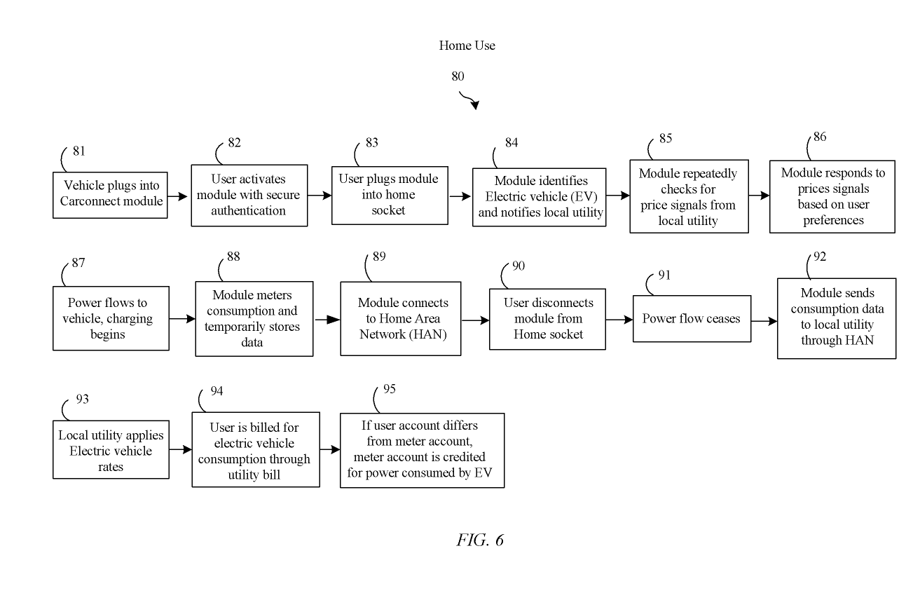

In block 46, the handle 1 periodically senses data regarding energy flow through the handle 1 (via energy sensor 10), and transmits the same to the energy provider via the communications interface 16 or PLC. The process then jumps back to block 43, whereupon it loops indefinitely through blocks 43, 45, 46 until the user disconnects the vehicle and/or the handle 1 from the connection to the electric power grid. The steps taken when the user disconnects the vehicle and/or the handle 1 from the connection will be discussed in relation to FIGS. 5-6.

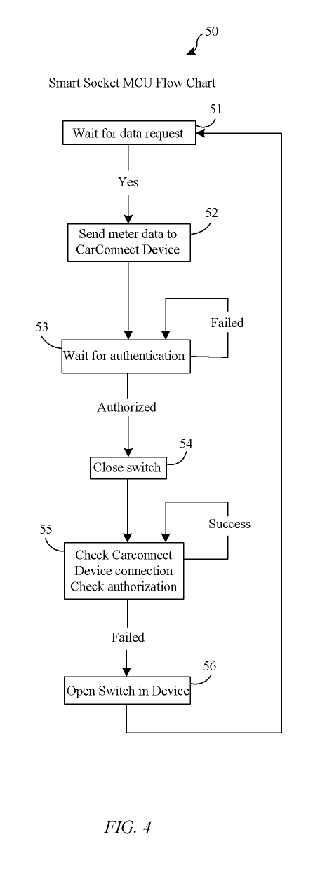

FIG. 4 is an embodiment of a flow chart 50 for MCU 27 in FIG. 2. As will be appreciated, this flow chart represents acts resulting from the application of logic to operate MCU 27, including logic embodied in flash memory 27b, but also potentially embodied in volatile memory, such as RAM, that is loaded from the flash memory 5b.

In block 51, the smart socket 20 waits for a request from the handle 1 for the identity of the socket 20 and its associated meter. When such a request is received, the process proceeds to block 52.

In block 52, the MCU 27 retrieves this information from flash memory 27b, and communicates it to the handle 1 via PLC. From block 52, the process proceeds to block 53.

In block 53, the socket 20 waits for an indication of utility authorization from the handle 1. If such indication is obtained via PLC, the process proceeds to close switches 25a, 25b as depicted in block 54. The process then proceeds to block 55.

In block 55, the socket 20 periodically checks the status of the connection and the utility authorization. If the connection and the utility authorization are both intact, the process loops. If either the connection or the utility authorization is no longer intact, the process proceeds to block 56.

In block 56, the process opens switches 25a, 25b, thus disabling the socket 20.

From block 56, the process jumps back to block 51, where it waits for another request for socket and meter identity.

FIG. 5 is timing diagram illustrating an embodiment of the timing of the events in the overall process of connecting a plug-in vehicle to the energy grid through a public or semi-public outlet. As will be seen, some of these events are manual steps performed by the end user, and some are performed by the MCU's 5, 27 operating pursuant to the flow charts of FIGS. 3-4.

In block 61, the user inserts the male plug from the vehicle's charging interface into the corresponding female socket on the handle 1.

Then, in block 62, the user activates the handle 1 after successfully authenticating himself/herself via security authentication device 6.

In block 63, the user inserts the male plug from the handle 1 into a smart socket 20 which is in turn coupled to an electrical outlet.

In block 64, the handle 1 identifies the socket 20 and the related meter. As previously explained, the handle 1 obtains this information from the socket 20 via BPL, with FIG. 4 depicting the process steps undertaken by MCU 27 in providing this information.

In block 65, the handle 1 communicates with the energy provider via the communications interface 16. In one embodiment, as previously explained, the handle 1 communicates via the access point (i.e., meter) for the outlet in the utility's Home Area Network (HAN).

In block 66, the handle 1 identifies the vehicle as a plug-in vehicle and notifies the energy provider of this identity through the connection established in block 65. This information is needed for the purpose of obtaining advantageous energy pricing from the utility.

In block 67, the energy provider validates the handle 1 and the user account. As previously explained, this is accomplished by sending the energy provider a unique access code for the user over the connection established in block 65. Using this information, the utility validates the handle 1 and the user's account, and transmits the results of this validation (i.e., successful or not) back to the handle 1 via BPL or the connection established via communications interface 16.

Assuming the validation is successful, block 68 is performed. In block 68, the handle 1 repeatedly checks for price signals from the energy provider such as a local utility. The utility communicates this information to the handle 1 over the connection established in block 65, assuming that connection is bi-directional, or via BPL.

Block 69 follows block 68. In block 69, the handle 1 responds to the price signals based on user preferences. For example, if the user has expressed a preference that charging not occur until the price of energy is at or below 10 cents per kilowatt hour, the handle 1 iterates until the price as reported from the utility meets this condition. At that point, the process proceeds to block 70.

In block 70, the handle 1 directs the socket 20 to close the socket switches (26a, 26b). In addition, if not already accomplished, the handle 1 closes the switch 14, allowing power to flow to the vehicle.

In block 71, the handle 1 meters the consumption of energy and stores this information.

In block 72, the end user unplugs the handle 1 from the socket 20 when the charging session is over or the user wishes to terminate the charging session.

In block 73, a breaker in the socket 20 disconnects, opening switches 26a, 26b, thus disabling the socket 20.

In block 74, the handle 1 sends the consumption data to the energy provider such as a local utility through the connection established in block 65.

In block 75, the energy provider such as a local utility calculates the amount owed for the energy consumption, using the preferred rates for electric vehicles.

In block 76, the energy provider such as a local utility charges the user's account with the amount calculated in block 75.

In block 77, the meter tied to the socket 20 is credited with the amount calculated in block 75. Then, the switch 14 in the handle 1 is opened, disabling the handle 1.

FIG. 6 is a timing diagram illustrating the timing of the key events in the overall process of connecting a plug-in vehicle to the energy grid through a private (i.e., home) outlet. As will be seen, some of these events are manual steps performed by the end user, and some are performed by the MCU's 5, 27 operating pursuant to the flow charts of FIGS. 3-4.

In block 81, the user inserts the male plug from the vehicle's charging interface into the corresponding female socket on the handle 1.

Then, in block 82, the user activates the handle 1 after successfully authenticating himself/herself via security authentication device 6.

In block 83, the user inserts the male plug from the handle 1 into the corresponding female socket of the home outlet.

In block 84, the handle 1 identifies the vehicle as a plug-in vehicle and notifies the energy provider such as a local utility of this identity. In one implementation, this is accomplished via BPL. This information is needed for the purpose of obtaining advantageous energy pricing from the utility.

In block 85, the handle 1 repeatedly checks for price signals from the energy provider such as a local utility. In one implementation, the utility communicates this information to the handle 1 via BPL. 10097] Block 86 follows block 85. In block 86, the handle 1 responds to the price signals based on user preferences. For example, if the user has expressed a preference that charging not occur until the price of energy is at or below 10 cents per kilowatt hour, the handle 1 iterates until the price as reported from the utility meets this condition. At that point, the process proceeds to block 87.

In block 87, the handle 1 directs the socket to close the socket switches (26a, 26b). In addition, if not already accomplished, the handle 1 closes the switch 14, allowing power to flow to the vehicle.

In block 88, the handle 1 meters the consumption of energy and stores this information.

In block 89, the handle 1 connects to the energy provider such as a local utility via the communications interface 16. In one embodiment, as previously explained, the handle 1 connects via the access point (i.e., meter) for the user's outlet in the utility's Home Area Network (HAN).

In block 90, the user unplugs the handle 1 from the socket 20 when the charging session is over or the user wishes to terminate the charging session. In response, a breaker in the socket 20 disconnects, opening switches 26a, 26b, and disabling the socket 20.

In block 91, energy flow to the vehicle ceases.

In block 92, the handle 1 sends the consumption data to the energy provider such as a local utility through the connection established in block 89.

In block 93, the energy provider calculates the amount owed for the energy consumption, using the preferred rates for electric vehicles.

In block 94, the energy provider such as a local utility charges the user's account with the amount calculated in block 93.

In block 95, if the user account differs from the meter account for the meter tied to the user outlet, the meter account is credited with the amount calculated in block 93. Then, the switch 14 in the handle 1 is opened, disabling the handle 1.

As can be seen from the foregoing, the main differences between the overall processes depicted in FIGS. 5-6 is that block 64 and 67 in the process depicted in FIG. 5 (public use) are eliminated from the process depicted in FIG. 6 (home use). These steps, where the handle 1 identifies the public or semi-public socket 20 and related meter (block 64), and the energy provider such as a local utility validates the handle 1 and the user account (block 67), are unnecessary in the process depicted in FIG. 6, where the user connects the handle 1 to a private outlet or socket in the user's own residence.

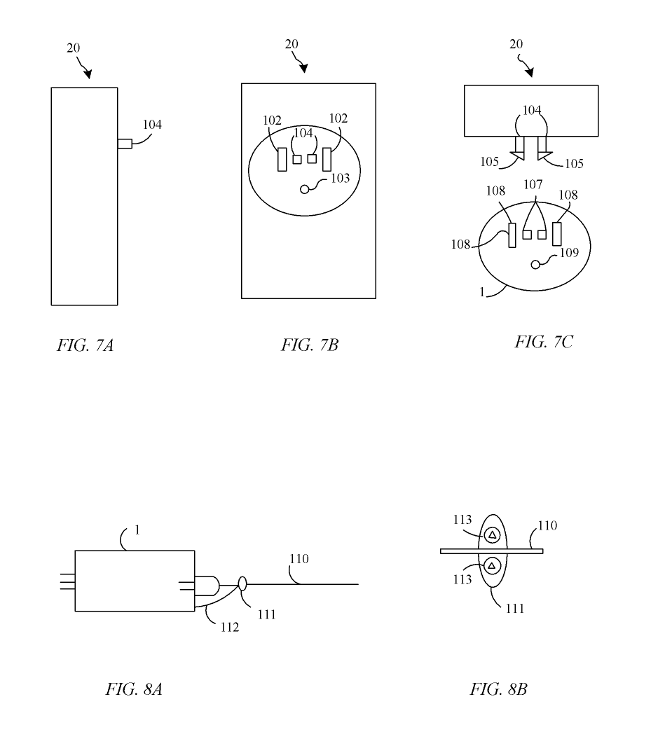

Preferably, the smart socket 20 and handle 1 of the invention includes mechanisms for preventing unauthorized removal of the handle 1 from the smart socket 20 during charging in order to prevent malicious or accidental tampering, unauthorized use of the handle 1, or energy theft. Referring to FIGS. 7A-C, smart socket 20 may include prongs 104 that extend outwardly from the smart socket 20 and include mechanisms 105 such as retractable barbs 105 that prevent removal of the handle 1 from the smart socket 20 during charging. The prongs 104 with retractable barbs 105 are preferably placed in close proximity to plug receptacles 102 and 104. The handle 1 includes female receptacles 107 that accommodate the prongs 104 when the barbs 105 are retracted, but do not allow the socket 20 to be removed when the barbs 105 are extended. The female receptacles 107 are placed in the same relative proximity to the plugs 108 and 109 as the prongs 104 are to the plug receptacles 102 and 104.

The retractable barbs 105 allow a locking connection between the smart socket 20 and the handle 1 that is activated, for example, after the user has been authenticated during charging. The retractable barbs 105 may automatically retract once the charge is complete and the smart socket 20 deactivates the flow of electricity to the handle 1. Alternatively, the user may manually stop the charging process and thus retract the retractable barbs 105. Preferably, the user must be authenticated using the aforementioned systems and methods in order to disengage the barbs 105 and thus release the handle 1 from the smart socket 20. While this embodiment shows the prongs 104 with barbs 105 attached to the smart socket 20, in alternative embodiments, the locking mechanism may be part of the handle 1 instead of or in addition to the locking mechanism described as part of the smart socket 20.

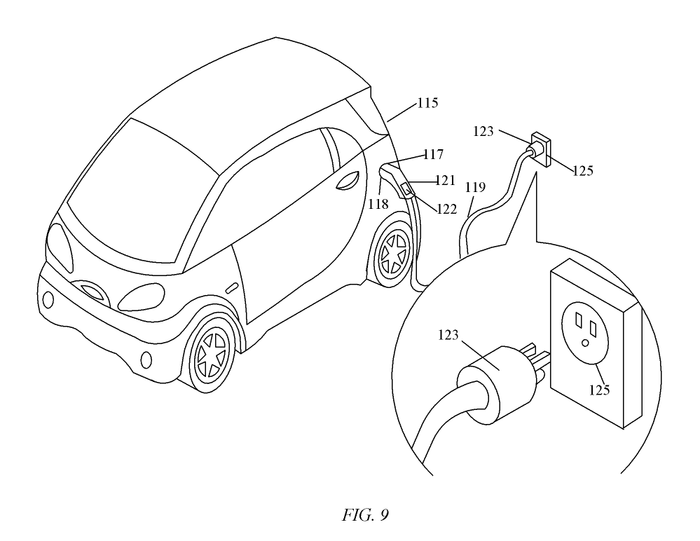

It is also preferable to include a mechanism to prevent unintentional or unauthorized disconnection of a vehicle plug from the handle 1. For example, a vehicle plug maybe stepped on or kicked during charging, preventing the vehicle from receiving an adequate charge. FIGS. 8A and 8B show an embodiment that includes a tether cable 112 and securing bracket 111 that prevents unintentional or unauthorized disconnection of the vehicle plug 110 from the handle 1. In a preferred embodiment, the securing bracket 111 is secured to the vehicle plug 110 using screws or fasteners with nonstandard heads to prevent unauthorized users from disconnecting the securing bracket 111 from the vehicle plug 110 and disconnecting the vehicle plug 110 from the handle 1. The authorized user may be provided a tool that fits the non-standard screw heads to fasten or release the securing bracket 111 from the vehicle plug 110. In other embodiments, the securing bracket 111 may be fitted with a lock and only the authorized user is provided a key that opens the lock.

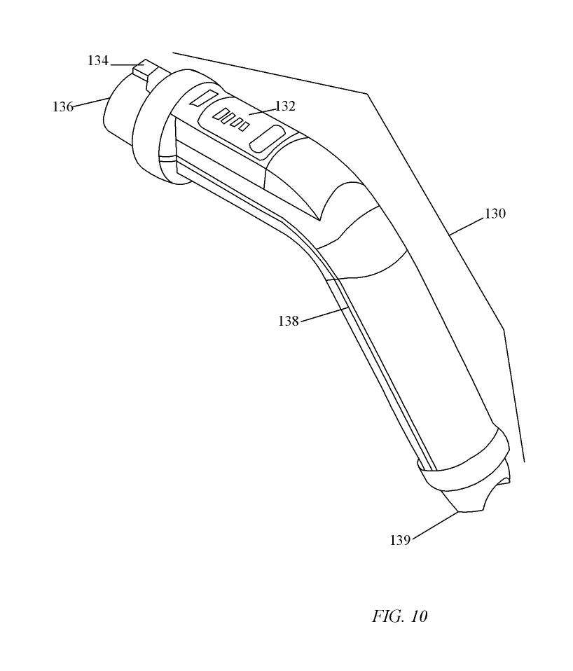

FIG. 9 is an embodiment of an EVCC 119. The EVCC 119 has a first interface 118 which connects with the vehicle 115 at socket 117 and a second interface 123 which connects with an outlet 125 using a plug 123. The outlet 125 may be a smart socket 20, a standard household receptacle (e.g. 110V, 115V, 120V, 220V, 127V, 230V, 110/220V, 120-127V, 127/230V, 100V, 127/220V, 220/230V, 231V, 240V), or a dedicated charging station (120V, 240V or 480V). The EVCC 119 further comprises a handle 121. The handle 121 comprises means for displaying, receiving, and transmitting data to and from the vehicle, the consumer and the energy provider as described for example for handle 1. The handle 121 contains pre-programmed or receives operator specific information. In some embodiments, operator specific data may be stored on computer readable media. The operator may be identified using a key, keyless system, biometric scanning, password, or code entry. Such information may be inputted directly into the handle 121, or transmitted to the handle 121 by a wired or wireless device including cellular, IEEE 802.11 (WiFi), IEEE802.15.4 (ZigBee) radios, WiMAX, BlueTooth, satellite, PLC communication, RFID or any other such devices. The handle 121 comprises logic to verify the operator specific information.

The handle 121 has a pistol shape, with the electrical supply cord coupling to the handle at a butt of the pistol shape, and A/C to D/C power conversion logic located in the butt of the pistol shape. The metering logic is located at least partially in a barrel of the pistol shape. Personal safety system logic is removed from the handle and located farther down the cord, within 12 inches of the supply socket.

Based on the operator specific information, logic in the handle 121 allows electricity to flow to or from the electric vehicle and bill or credit the energy exchange to the appropriate account. In some embodiments, the handle 121 transmits information regarding the energy exchange in a real time fashion. In other embodiments, the handle 121 transmits information regarding the energy exchange once the vehicle is disconnected from the electric vehicle charging connection 119. The handle 121 further comprises logic to receive and display information regarding the status of the vehicle including, but not limited to indicators for testing, charging, discharging, draining, idling, error, charging complete, rate of charge, communication of the vehicle and smart socket, relative energy pricing, utility events, grid conditions, demand or access fees, power on, power off, or any other such indicator relating to charging the vehicle. Wired and/or wireless communications logic may be used to enable the integration of ANSI metering as specified by the utility or other energy provider for specific service territories.

Energy flow to the vehicle 115 is controlled by signals sent between the EVCC 121 and the vehicle 115. The control pilot is the primary control conductor that is connected to the equipment ground through control circuitry on the vehicle and confirms that the vehicle is connected, permits charging/discharging of the supply, transmits the EVSE current rating to the vehicle, monitors the presence of the equipment ground and establishes vehicle ventilation requirements. An electric vehicle 115 determines the nature of and available current from the by measuring the pulse width of the pilot signal. The EVSE 119 may modify the pilot signal pulse width at any time, commanding the electric vehicle to increase or decrease the maximum AC current draw in accordance with SAEJ1772 or other protocols. Electric vehicles respond to the pilot signal by applying a resistor/diode combination to complete the pilot circuit.

The national electric code for EVCCs requires that a personal safety system (PSS), such as a ground fault circuit interrupter (GFCI), be either part of the socket or installed within 12 inches of the socket for a 120V system or within the EVSE for 240V systems. Unconventionally, the EVCC described herein separates the PWM signal generator from the GFCI/PSS logic by reconfiguring the logic within the handle 121. Communication between the EVCC and a smart socket is carried out using Power Line Carrier (PLC) technology. All communication between a smart socket and the EVCC 121 is therefore routed on the cable through the GFCI. The cable between the EVCC 121 and the smart socket therefore only needs to contain three wires: hot, neutral, and ground, and does not need an additional communication wire.

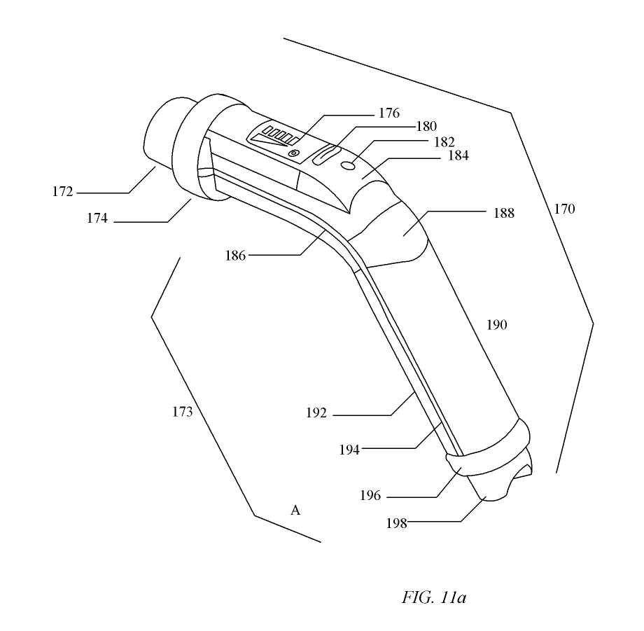

FIG. 10 is an embodiment of an exemplary configuration of the handle 121. The handle 121 includes a connector 136 with a release/locking mechanism 134 that connects with the vehicle (not shown), a display 132 and a light bar 138. In some embodiments the EVCC comprises a means to provide swivel strain relief 139 to a cord (not shown). The handle 121 may further comprise means for receiving, transmitting or displaying information regarding the status of the charging system. Such a display means may be integrated into the EVCC handle or the data may be sent to another device including but not limited to, smart phones, computers, utility AMI, cloud applications, tablets, personal digital assistants or the like using for example cellular, IEEE 802.11 (WiFi), IEEE 802.15.4 (ZigBee) radios, WiMAX, BlueTooth, satellite, PLC communication, RFID or any other such devices. For example, in some embodiments, the EVCC handle may include a light bar 138. Such a light bar may be located in any part of the EVCC handle that is useful. In some embodiments, as shown, it may follow the length of the handle 121. The light bar can display one or more colors with varying intensities and frequencies indicating one or more charging states. For example, the light bar may indicate if the EVCC is connected to an outlet, if power is flowing from the outlet, if power is reaching the car, if the car is charging, if it is running self tests, if it is charging, the rate at which it is charging, if charging is complete, if there is an error, if the vehicle is discharging energy, or if the vehicle is supplying power to the grid. Such information may be conveyed by the intensity of the light, for example, a dimly glowing light may indicate that it is charging, a pulsing light may indicate the rate of charge, a green light may indicate that it is fully charged, a red light may indicate an error, or any combination of colors, intensities and frequencies as are useful to convey status information to the user.

In some embodiments, the handle 121 may further comprise a display 132 which can convey the same or different information as the light bar 138. For example, the display may indicate if the EVCC is plugged into an outlet, if the EVCC is locked to the vehicle, if the handle 121 and the smart socket 20 are communicating with each other or sending a wireless signal, the relative price of electricity, an indication of an active demand reduction event as issued by the utility, an indication that the vehicle is not being charged, or one or more error codes.

Information from the handle 121 may be communicated to an independent device such as a smart phone, computer, utility AMI, cloud application, tablet, personal digital assistant, or the like. Some or all of the information may be displayed on the EVCC handle and/or an independent device.

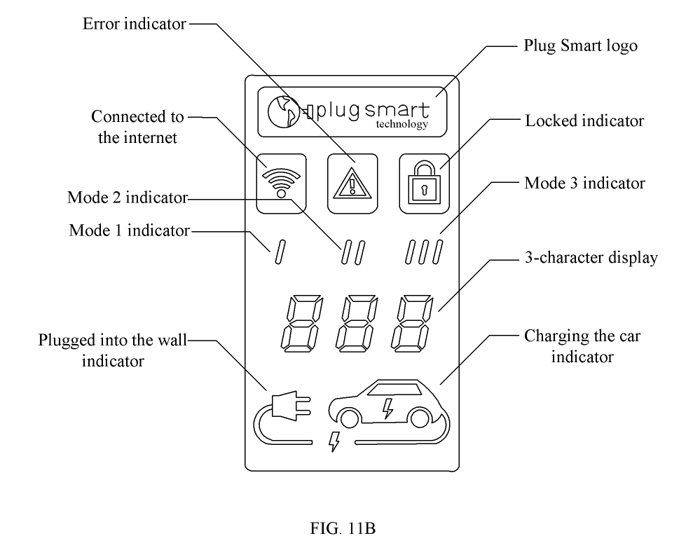

Further details of an embodiment of an EVCC handle 121 are illustrated in FIG. 11A. The handle 121 may include one or more of the components described in any combination. The handle 121 can include a coupler 172 to connect the vehicle to the EVCC. The coupler 172 may be a conductive or inductive coupler. In some embodiments, the coupler 172 is a SAE J1772 compliant connector. In another embodiment, it is an IEC 62196 compliant connector. In one embodiment, it is a Mennekes connector. In another embodiment it may be a JAM Level 3 DC connector. The connector 172 may include a metal release/locking latch (not shown). Such a latch may be activated using a latch release button 188. A front drag bumper 174 sits between the connector 172 and the housing 173. The display 176 may be configured to indicate if the EVCC is plugged into an outlet, if the EVCC is locked to the vehicle, if the EVCC and/or the smart socket are communicating with each other or sending a wireless signal, the relative price of electricity, an indication of an active demand reduction event as issued by the utility, an indication that the vehicle is not being charged, or one or more error codes. An exemplary display 176 is shown in FIG. 11B including LEDs which may be used to convey information such as rate or charge or pricing information and an assortment of additional indicating icons. The icons may include, but are not limited to currency, charging status, rate of charge, if the EVCC is locked to the vehicle, if the user has been authenticated, pricing of energy, etc.

An example of display status information is:
A. Plugged into the wall receptacle (on/off)
B. The EVCC is locked to the vehicle (on/off)
C. The EVCC and/or the smart socket are communicating with a) each other or b) with the internet
D. The actual price of electricity with three-character display capabilities
E. An indication of an active demand reduction event as issued by the utility (including, but not limited to, a Demand Response (DR) event)
F. An indication that the vehicle is not being charged

Returning to FIG. 11A, the EVCC handle may further include an override switch 180 which would allow the vehicle to continue charging regardless of any pre-programmed settings. In some embodiments, the override button can be multi-functional and provide additional features through various key press methods, for example, a particular pattern or length of depressing the button could reset the device. A locking feature 182 may additionally be included in the device. Such a locking feature may be a key way lock or a biometric sensor for verifying the identity of the individual using the device. The key way lock may be located underneath the vehicle latch release which will allow the user to lock the EVCC to the vehicle. When locked, the mechanical actuator to release the handle from the vehicle will not function, and the handle will not be removable from the vehicle without the associated key.

The EVCC handle may be further configured with a grip 190 including a heat sink 192. The handle may further include a light bar 186 that runs along all or part of the handle 170. The light bar can display one or more colors with varying intensities and frequencies indicating one or more charging states. For example, the light bar may indicate if the EVCC is connected to an outlet, if power is flowing from the outlet, if power is reaching the car, if the car is charging, if it is running self tests, if it is charging, the rate at which it is charging, if charging is complete, if there is an error, if the vehicle is discharging energy, or if the vehicle is supplying power to the grid. Such information may be conveyed by the intensity of the light, for example, a dimly glowing light may indicate that it is charging, a pulsing light may indicate the rate of charge, a green light may indicate that it is fully charged, a red light may indicate an error, or any combination of colors, intensities and frequencies as are useful to convey status information to the user. The light bar 186 may be edged with a sealing gasket 194. The handle may further comprise a lower drag bumper 196 and a mechanism 198 to relieve strain on a cord (not shown).

An example of status communication via a light bar is:

A. Off=not plugged into a wall receptacle
B. On (flashing)=booting and running self tests
C. On (dim)=plugged into a wall receptacle
D. On (pulsing)=charging the vehicle whereby the rate of charge (power) determines the frequency interval of the pulsing
E. On (bright)=charging complete
F. Alternative color (Flashing)=error

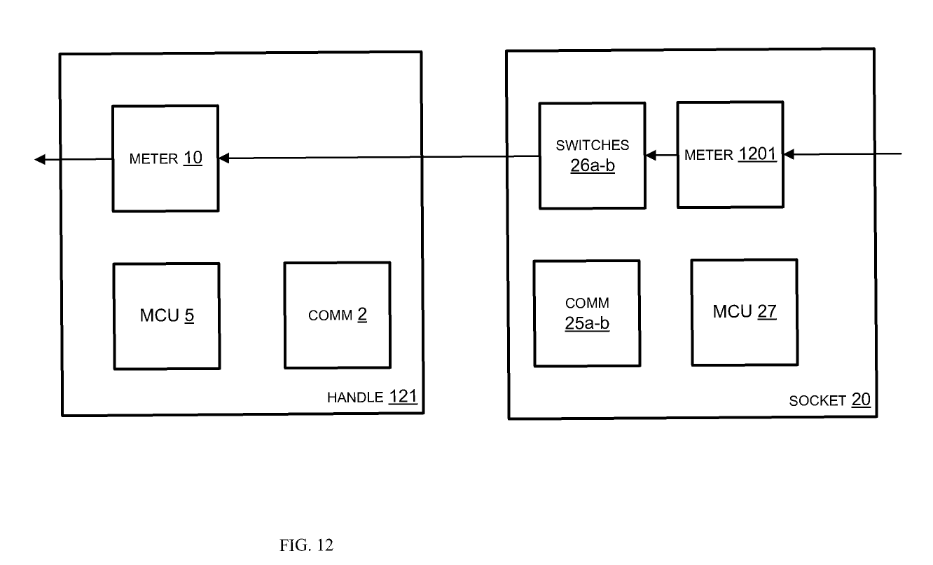

FIG. 12 is a view of an embodiment of dual metering logic in an EVCC. Unconventionally, a meter 1201 in the smart socket 20 communicates with a meter 10 in the handle 1. Both meters measure a flow of electricity through the respective device (e.g., amperage). However, utilizing communication interfaces 2 and 25a-b, respectively, the handle 1 and socket synchronize their meter measurements. Logic is included to disable electricity flow from the socket 20 (e.g., via switches 26a-b) if the meter measurements do not match within a tolerance that accounts for electricity consumption by the logic “intervening between” the socket meter 1201 and the handle meter 10. “Intervening” logic is logic that consumes power after the measurement by the meter 1201 but before or concurrently with the measurement by meter 10 (this can include the electricity consumed by meter 10 itself). Intervening logic may include logic to encode and transmit the metering information between the socket and the handle. The validation may take place in the socket 20 in order to simplify the calculation of electricity consumer by intervening logic. The synchronization and validation may include timing information about when each meter reading is taken, and a difference in the times may be used to calculate an amount of electricity consumed by intervening logic.

Meter readings that do not match within a configured tolerance may indicate siphoning of electricity between the socket 20 and the handle 121. A further level of metering validation involves determination that the amount of electrical flow through the socket 20 and/or the handle 121 is consistent with expected loading. For example, certain EVs with certain battery types may be expected to draw a certain amount of current (possibly further depending on battery age and charge level). If the metered amount at either or both of the socket 20 and handle 121 doesn't match these expectations, the flow of electricity through the socket 20 may be disabled.

The PLC communication between the handle 1 and the socket 20 may be encrypted to protect from other devices attempting to communicate with the handle 1 or socket 20. The handle 1 and socket 20 may communicate by means other than PLC, for example using short-range RF technologies such as Bluetooth.

In one embodiment, an authentication request from a handle is broadcast to multiple sockets sharing a same power supply line. All of the sockets attempt to authenticate with the handle. Each socket then compares its metering information with metering information from the handle. Only the handle which determines a match between its metering information and the metering information provided by the handle will successfully authenticate with the handle. Thus, in one embodiment, a user plugs a handle into an electric vehicle, and electricity begins to flow from the socket to the handle to the electric vehicle, prior to authentication of the user with the power supplier, and prior to authentication between the handle and the socket. Multiple sockets sharing the same power supply line as the handle attempt to authenticate with the handle. Each socket compares its meter reading(s) to a meter reading(s) broadcast by the handle on the power supply line. A socket which makes a successful comparison, within a tolerance determined in part by a predetermined power consumption of logic intervening between the socket meter logic and the handle meter logic, successfully authenticates with the handle, and the other sockets do not successfully authenticate with the handle. The handle or socket, or both, then disconnect power flow to the electric vehicle in the user authentication with the power supplier is not successful, or if the user's account is restricted (for example due to nonpayment). Otherwise, power continues to flow from the socket through the handle to the electric vehicle.

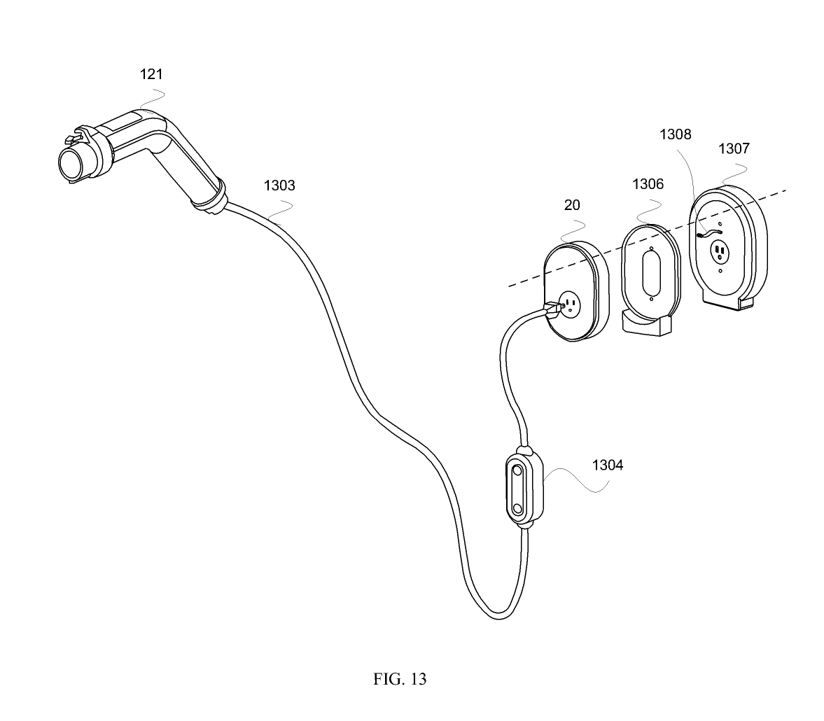

FIG. 13 illustrates an embodiment of an EVCC including an expansion module. The EVCC includes a handle 121, cord 1303, PSS module 1304, smart socket 1304, adapter 1306, and a smart socket expansion module 1307. The cord 1303 includes only three wires: hot, neutral, and ground. The PSS 1304 is within 12 inches of the socket 20. Data signals are passed between the handle 121 and the socket 20 through the PSS 1304 via PLC. The socket 20 couples to an expansion module 1307 via an adapter 1306.

The expansion module 1307 may include the socket meter logic 1201 and/or enhanced communications capabilities. The expansion module may be configured with wired and wireless communications logic to enable the integration of ANSI metering as specified by the utility for specific service territories. Electricity and PLC data (which is broadcast to all sockets on the same utility line) may be passed between the socket 20 and the expansion module 1307. Data which is not intended for broadcast to all sockets on the utility line, such as an id of the connected handle 121 or metering information, may be communicated from the socket 20 to the expansion module 1307 over a separate data cable 1308. In addition to metering, the expansion module may include logic to enable forms of communications such as cellular, IEEE 802.11 (WiFi), or IEEE 802.15.4 (ZigBee) radios to enhance communication with the Internet or the utility AMI.

The expansion module can interface with the smart socket via a USB or other port to allow for the integration of ANSI metering as specified by the utility for specific service territories. The expansion module can be owned by the utility and installed on their customer's premises, whereas the smart socket 20 may be the property of the another party, such as the premise owners.

In one embodiment, a handle that interfaces between an electric supply socket and an electric vehicle an electrical supply cord interfacing the handle to the socket. The electrical supply cord consists of exactly one hot wire, one neutral wire, and one ground wire. Metering logic in the handle provides a measure of electric load on the handle. The handle communicates measurements of electric load on the handle to the socket during an authentication process with the socket. The handle has a pistol shape, with the electrical supply cord coupling to the handle at a butt of the pistol shape, and A/C to D/C power conversion logic located in the butt of the pistol shape. The metering logic is located at least partially in a barrel of the pistol shape. The handle includes a visual indication of a charging status of the electric vehicle (e.g., a light bar) along the butt and barrel of the handle. The light bar shows charging statuses of the electric vehicle by varying both intensity and a display pattern, and possibly also using different colors. The handle communicates measurements of the electric load to the socket during a charging session with the electric vehicle. The handle may further include a display and logic to indicate on the display an actual price of electricity provided by the handle, and an indication of an active demand reduction event as issued by a power supply utility, among other things.

Although embodiments are described herein having one meter in the socket and another in the handle, these are not the only places the meters could be located. For example, in some embodiments one of the meters is not in the socket but is instead located elsewhere along the power supply line, for example behind the wall or in the fuse box. In other embodiments one of the meters may be located in the vehicle itself, or elsewhere along the cord not in the handle.

### Implementations and Alternatives

Those having skill in the art will appreciate that there are various logic implementations by which processes and/or systems described herein can be effected (e.g., hardware, software, and/or firmware), and that the preferred vehicle will vary with the context in which the processes are deployed. “Software” refers to logic that may be readily readapted to different purposes (e.g. read/write volatile or nonvolatile memory or media). “Firmware” refers to logic embodied as read-only memories and/or media. Hardware refers to logic embodied as analog and/or digital circuits. If an implementer determines that speed and accuracy are paramount, the implementer may opt for a hardware and/or firmware vehicle; alternatively, if flexibility is paramount, the implementer may opt for a solely software implementation; or, yet again alternatively, the implementer may opt for some combination of hardware, software, and/or firmware. Hence, there are several possible vehicles by which the processes described herein may be effected, none of which is inherently superior to the other in that any vehicle to be utilized is a choice dependent upon the context in which the vehicle will be deployed and the specific concerns (e.g., speed, flexibility, or predictability) of the implementer, any of which may vary. Those skilled in the art will recognize that optical aspects of implementations may involve optically-oriented hardware, software, and or firmware.

The foregoing detailed description has set forth various embodiments of the devices and/or processes via the use of block diagrams, flowcharts, and/or examples. Insofar as such block diagrams, flowcharts, and/or examples contain one or more functions and/or operations, it will be understood as notorious by those within the art that each function and/or operation within such block diagrams, flowcharts, or examples can be implemented, individually and/or collectively, by a wide range of hardware, software, firmware, or virtually any combination thereof. Several portions of the subject matter described herein may be implemented via Application Specific Integrated Circuits (ASICs), Field Programmable Gate Arrays (FPGAs), digital signal processors (DSPs), or other integrated formats. However, those skilled in the art will recognize that some aspects of the embodiments disclosed herein, in whole or in part, can be equivalently implemented in standard integrated circuits, as one or more computer programs running on one or more computers (e.g., as one or more programs running on one or more computer systems), as one or more programs running on one or more processors (e.g., as one or more programs running on one or more microprocessors), as firmware, or as virtually any combination thereof, and that designing the circuitry and/or writing the code for the software and/or firmware would be well within the skill of one of skill in the art in light of this disclosure. In addition, those skilled in the art will appreciate that the mechanisms of the subject matter described herein are capable of being distributed as a program product in a variety of forms, and that an illustrative embodiment of the subject matter described herein applies equally regardless of the particular type of signal bearing media used to actually carry out the distribution. Examples of a signal bearing media include, but are not limited to, the following: recordable type media such as floppy disks, hard disk drives, CD ROMs, digital tape, and computer memory.

In a general sense, those skilled in the art will recognize that the various aspects described herein which can be implemented, individually and/or collectively, by a wide range of hardware, software, firmware, or any combination thereof can be viewed as being composed of various types of “circuitry.” Consequently, as used herein “circuitry” includes, but is not limited to, electrical circuitry having at least one discrete electrical circuit, electrical circuitry having at least one integrated circuit, electrical circuitry having at least one application specific integrated circuit, circuitry forming a general purpose computing device configured by a computer program (e.g., a general purpose computer configured by a computer program which at least partially carries out processes and/or devices described herein, or a microprocessor configured by a computer program which at least partially carries out processes and/or devices described herein), circuitry forming a memory device (e.g., forms of random access memory), and/or circuitry forming a communications device (e.g., a modem, communications switch, or optical-electrical equipment).

Those skilled in the art will recognize that it is common within the art to describe devices and/or processes in the fashion set forth herein, and thereafter use standard engineering practices to integrate such described devices and/or processes into larger systems. That is, at least a portion of the devices and/or processes described herein can be integrated into a network processing system via a reasonable amount of experimentation.

The foregoing described aspects depict different components contained within, or connected with, different other components. It is to be understood that such depicted architectures are merely exemplary, and that in fact many other architectures can be implemented which achieve the same functionality. In a conceptual sense, any arrangement of components to achieve the same functionality is effectively “associated” such that the desired functionality is achieved. Hence, any two components herein combined to achieve a particular functionality can be seen as “associated with” each other such that the desired functionality is achieved, irrespective of architectures or intermedial components. Likewise, any two components so associated can also be viewed as being “operably connected”, or “operably coupled”, to each other to achieve the desired functionality.

We claim:

1. An electric vehicle charging connection (EVCC) comprising:
first metering logic within a socket that supplies electricity to a plug-in cord;
second metering logic within a handle connected to the plug-in cord; and
logic for the handle and socket to compare metering information from the first and second metering logic, and to disable electrical flow from the socket based on a result of the comparison.

2. The EVCC of claim 1, wherein the comparison involves comparing how much electricity is flowing from the socket to how much electricity is flowing to the handle, accounting for electrical consumption by intermediate logic.

3. The EVCC of claim 1, wherein the first metering logic is located within a utility owned expansion module that is coupled to a facility owned electrical socket.

4. The EVCC of claim 1, the cord between the socket and the handle comprising personal safety system logic, the handle and socket comprising logic to communicate metering data via power lines that pass through the personal safety system logic, the cord comprising only hot, neutral, and ground wires.

5. The EVCC of claim 3, further comprising the socket and the expansion module communicating via a data cable that is distinct from power lines via which data may be communicated to all sockets on a same power supply line as the socket.

6. The EVCC of claim 1, the handle having a pistol shape, a grip of the pistol shape comprising power conversion logic, a barrel of the pistol shape comprising at least part of the second metering logic.

7. The EVCC of claim 1, the socket comprising logic to authenticate with the handle only if the metering information from the first metering logic matches the metering information from the second metering logic.

8. A handle to interface between an electric supply socket and an electric vehicle, the handle comprising:
an electrical supply cord interfacing the handle to the socket, the electrical supply cord consisting of exactly one hot wire, one neutral wire, and one ground wire;
metering logic to provide a measure of electric load on the handle; and
logic to communicate the measure of electric load to the socket during an authentication process with the socket.

9. The handle of claim 8, further comprising:
the handle having a pistol shape;
the electrical supply cord coupling to the handle at a butt of the pistol shape; and
A/C to D/C power conversion logic located in the butt of the pistol shape, and the metering logic located at least partially in a barrel of the pistol shape.

10. The handle of claim 9, further comprising:
a visual indication of a charging status of the electric vehicle, the visual indication in the form of a light bar along the butt and barrel of the handle.

11. The handle of claim 10, comprising logic to distinguish multiple possible charging statuses of the electric vehicle using both intensity and a display pattern.

12. The handle of claim 8, further comprising logic to provide ongoing measurements of the electric load to the socket during a charging session with the electric vehicle.

13. The handle of claim 8, further comprising a display and logic to indicate on the display an actual price of electricity provided by the handle, and an indication of an active demand reduction event as issued by a power supply utility.

14. An electric vehicle charging system comprising:
first metering logic that measures a supply of electricity to a plug-in cord for an electric vehicle;
second metering logic along a length of the plug-in cord; and
logic to compare metering information from the first and second metering logic, and to disable electrical flow to the plug-in cord based on a result of the comparison.

15. The system of claim 14, wherein the comparison involves comparing how much electricity is flowing at locations of the first and second metering logic, accounting for electrical consumption by intermediate logic.

16. The system of claim 14, the plug-in cord comprising only hot, neutral, and ground wires.

17. The system of claim 14, the plug-in cord comprising a handle having a pistol shape, a grip of the pistol shape comprising power conversion logic, a barrel of the pistol shape comprising at least part of the second metering logic.
